(19) United States
(12) Patent Application Publication
(10) Pub. No.: US 2021/0030070 A1
(43) Pub. Date: Feb. 4, 2021

(54) ELECTRONIC ATOMIZATION DEVICES, METHODS FOR HEATING CONTROL, AND COMPUTER DEVICES

(71) Applicant: SHENZHEN SMOORE TECHNOLOGY LIMITED, Shenzhen (CN)

(72) Inventors: Changwen SUN, Shenzhen (CN); Weiming FANG, Shenzhen (CN); Zhenggen DAI, Shenzhen (CN); Jun ZHOU, Shenzhen (CN); Xinyu WANG, Shenzhen (CN); Xin ZHANG, Shenzhen (CN); Wenjie DONG, Shenzhen (CN); Lijun KANG, Shenzhen (CN)

(21) Appl. No.: 16/941,802

(22) Filed: Jul. 29, 2020

(30) Foreign Application Priority Data
Jul. 30, 2019 (CN) 2019106962440

(51) Int. Cl. A24F 40/57; A24F 40/10; A24F 40/53; A24F 40/60; G05B 19/4155; G01R 27/14

(52) U.S. Cl. CPC A24F 40/57; A24F 40/10; A24F 40/53; G05B 2219/42237; G05B 19/4155; G01R 27/14; A24F 40/60

(57) ABSTRACT

An electronic atomization device is disclosed, including: an atomization unit, configured to heat liquid in the electronic atomization device to atomize the liquid; and a control unit, configured to: send a PWM control signal to the atomization unit, and the PWM control signal is configured to control the atomization unit to heat at a constant temperature kept to the target temperature; calculate the effective output power of the atomization unit; determine whether the oil content of the atomization unit is abnormal according to the effective output power; and control the atomization unit to output the reduced power or stop heating, when it is determined that the oil content of the atomization unit is abnormal.

### CROSS-REFERENCE TO RELATED APPLICATIONS

This application claims priority to Chinese Patent Application No. 2019106962440 filed on Jul. 30, 2019, the disclosure of which is hereby incorporated by reference in its entirety.

### TECHNICAL FIELD

The present disclosure relates to the technical field of electronic atomization devices, and more particularly, to electronic atomization devices, methods for heating control, and computer devices.

### BACKGROUND

An electronic cigarette is also known as a virtual cigarette or an electronic atomization device. As a substitute for cigarette, the electronic cigarette has a similar appearance and taste to those of a conventional cigarette, while it does not contain tar suspended particles and other harmful ingredients.

An electronic atomization device generally includes a liquid storage unit, an atomization unit, and a battery unit. In the existing electronic atomization device, the purpose of preventing dry burning is mainly to prevent the generation of harmful substances and burnt smell. Because once the burnt smell is generated, some unhealthy substances will be produced, thereby endangering human health. The main reason for the generation of harmful gas and burnt smell during the heating process of the electronic atomization device is that the liquid continues to be heated after being exhausted, and the liquid flow in the liquid guiding element in the atomization unit is poor, resulting in the liquid in the liquid storage unit not being smooth guided to the heating element of the atomization unit and the temperature in the heating process is so high that harmful substances is produce.

### SUMMARY

Accordingly, it is necessary to provide an electronic atomization device, a method and device for heating control, and a storage medium, which can prevent dry burning in view of the above technical problems.

According to an aspect of the present disclosure, an electronic atomization device is provided, which includes an atomization unit and a control unit.

The atomization unit is configured to heat liquid in the electronic atomization device to atomize the liquid. The control unit is configured to: send a PWM control signal to the atomization unit, and the PWM control signal is configured to control the atomization unit to heat at a constant temperature kept to a target temperature; calculate an effective output power of the atomization unit; determine whether oil content of the atomization unit is abnormal according to the effective output power; and control the atomization unit to output a reduced power or stop heating, when it is determined that the oil content of the atomization unit is abnormal.

In an embodiment, the control unit includes a microprocessor and a sampling circuit.

The microprocessor is configured to send a PWM control signal to the atomization unit, and the PWM control signal is configured to control the atomization unit to heat at a constant temperature kept to the target temperature. The sampling circuit is configured to acquire a real-time resistance of the atomization unit and send the real-time resistance to the microprocessor. The microprocessor is further configured to determine a real-time temperature of the atomization unit according to the real-time resistance, and adjust the PWM control signal according to a difference between the real-time temperature and the target temperature to adjust the real-time temperature of the atomization unit to obtain the target temperature.

In an embodiment, each PWM cycle of the PWM control signal includes a plurality of power-on phases and power-off phases.

The sampling circuit is further configured to acquire a heating resistance of the atomization unit in each power-off phase during one preset time cycle, and send the heating resistance to the microprocessor. The microprocessor is further configured to: acquire an output voltage of a power supply of the electronic atomization device in each power-on phase during the preset time cycle, and acquire a duty ratio of the PWM cycle corresponding to a respective output voltage and heating resistance during the preset time cycle; calculate a plurality of effective output powers during the preset time cycle according to each output voltage, each heating resistance and the corresponding duty ratio; and control the atomization unit to output the reduced power or stop heating, if each effective output power is less than a preset power threshold.

In an embodiment, the electronic atomization device further includes a prompt unit configured to provide a user prompt adapted to prompt a user the atomization unit has the abnormal liquid content.

The microprocessor is further configured to generate the user prompt in response to determining the atomization unit has the abnormal liquid content.

In an embodiment, the prompt unit includes at least one of a display screen and a voice prompter.

In an embodiment, the sampling circuit includes: a MOS transistor Q1, a diode D1, a resistor R1 and a resistor R2.

The MOS transistor Q1 has a gate electrically connected to an ADC sampling terminal of the microprocessor, a drain electrically connected to a first end of the resistor R1, and a source electrically connected to a power supply. The second end of the resistor R1 is electrically connected to a cathode of the diode D1, and an anode of the diode D1 is grounded. The cathode of the diode D1 is further electrically connected to an output terminal of the microprocessor, the output terminal of the microprocessor is further electrically connected to a first end of the atomization unit, and a second end of the atomization unit is grounded. The resistor R2 has a first end electrically connected to the gate of the MOS transistor Q1, and a second end electrically connected to the source of the MOS transistor Q1.

According to another aspect of the present disclosure, a method for heating control applied to the electronic atomization device is also provided. The electronic atomization device includes an atomization unit configured to heat liquid in the electronic atomization device to atomize the liquid, and a control unit. The control unit executes the heating control method, and the heating control method includes: sending a PWM control signal to the atomization unit, wherein the PWM control signal is configured to control the atomization unit to heat at a constant temperature kept to a target temperature; calculating an effective output power of the atomization unit; determining whether oil content of the atomization unit is abnormal according to the effective output power; and controlling the atomization unit to output a reduced power or stop heating when it is determined that the oil content of the atomization unit is abnormal.

In an embodiment, the calculating the effective output power of the atomization unit includes: each PWM cycle of the PWM control signal includes a plurality of power-on phases and power-off phases; acquiring an output voltage of a power supply of the electronic atomization device in each power-on phase during one preset time cycle; acquiring a heating resistance of the atomization unit in each power-off phase during the preset time cycle; acquiring a duty ratio of the PWM cycle corresponding to each output voltage and heating resistance during the time period; and calculating a plurality of effective output powers during the time period according to each output voltage, each heating resistance and a corresponding duty ratio.

In an embodiment, the determining whether the oil content of the atomization unit is abnormal according to the effective output power includes: determining the oil content of the atomization unit is abnormal if each effective output power is less than a preset power threshold.

In an embodiment, the electronic atomization device further includes a prompt unit, the method further includes: generating prompt information adapted to prompt the user that the liquid content of the atomization unit is abnormal, if each effective output power is less than the power threshold; and sending the prompt information to the prompt unit for presentation.

In an embodiment, the controlling the atomization unit to heat at a constant temperature kept to the target temperature includes: acquiring a real-time temperature of the atomization unit; and adjusting the real-time temperature of the atomization unit according to the target temperature.

In an embodiment, the adjusting the real-time temperature of the atomization unit according to a target temperature includes: acquiring an initial resistance and an initial temperature of the atomization unit in an unheated state; calculating a target resistance of the atomization unit when heating to the target temperature according to the initial resistance, the initial temperature, the temperature coefficient of resistance and the preset target temperature of the atomization unit; acquiring a heating resistance through an ADC sampling method; and adjusting the PWM control signal by means of a PID algorithm to adjust the real-time temperature of the atomization unit, when an absolute value of a difference between the heating resistance and the target resistance is greater than a lower limit of a preset difference range and less than an upper limit of the difference range.

In an embodiment, the adjusting the real-time temperature of the atomization unit according to the target temperature includes: controlling the atomization unit to heat with the maximum output power, when the absolute value of the difference between the heating resistance and the target resistance is less than the lower limit of the difference range.

In an embodiment, the acquiring an initial resistance of the atomization unit in an unheated state includes: sampling the resistance of the atomization unit at a preset sampling frequency, in respond to identifying loading of the cartridge; comparing the acquired resistances; determining the resistances as the initial resistance of the atomization unit in the unheated state, if the resistances are all equal; updating the initial resistance record; and acquiring the initial resistance determined in the last time from the initial resistance record as the initial resistance of the atomization unit in the unheated state, if the acquired resistances change with the acquisition time.

According to another aspect of the present disclosure, a computer device applied to an electronic atomization device is also provided. The electronic atomization device includes an atomization unit configured to heat the liquid in the electronic atomization device to atomize the liquid. The computer device includes a processor, and a memory on which instructions are stored. When the instructions are executed by the processor, the processor is caused to perform the following steps: sending a PWM control signal to the atomization unit, wherein the PWM control signal is configured to control the atomization unit to heat at a constant temperature kept to the target temperature; calculating an effective output power of the atomization unit; determining whether oil content of the atomization unit is abnormal according to the effective output power; and controlling the atomization unit to output the reduced power or stop heating when it is determined that the oil content of the atomization unit is abnormal.

In an embodiment, each PWM cycle of the PWM control signal includes a plurality of power-on phases and power-off phases, and the step of calculating the effective output power of the atomization unit includes: acquiring an output voltage of a power supply of the electronic atomization device in each power-on phase during one preset time cycle; acquiring a heating resistance of the atomization unit in each power-off phase during the preset time cycle; acquiring a duty ratio of the PWM cycle corresponding to each output voltage and heating resistance during the time period; and calculating a plurality of effective output powers during the time period according to each output voltage, each heating resistance and a corresponding duty ratio.

In an embodiment, the step of determining whether the oil content of the atomization unit is abnormal according to the effective output power includes: determining the oil content of the atomization unit is abnormal if each effective output power is less than a preset power threshold.

In an embodiment, when the instructions are executed by the processor, the processor is caused to further perform the following steps: generating prompt information adapted to prompt the user that the liquid content of the atomization unit is abnormal, if each effective output power is less than the power threshold; and sending the prompt information to the prompt unit for presentation.

In an embodiment, the step of controlling the atomization unit to heat at a constant temperature kept to the target temperature includes: acquiring a real-time temperature of the atomization unit; and adjusting the real-time temperature of the atomization unit according to the target temperature.

In an embodiment, the step of adjusting the real-time temperature of the atomization unit according to the target temperature includes: acquiring an initial resistance and an initial temperature of the atomization unit in an unheated state; calculating a target resistance of the atomization unit when heating to the target temperature according to the initial resistance, the initial temperature, the temperature coefficient of resistance and the preset target temperature of the atomization unit; acquiring a heating resistance through an ADC sampling method; and adjusting the PWM control signal by means of a PID algorithm to adjust the real-time temperature of the atomization unit, when an absolute value of the difference between the heating resistance and the target resistance is greater than a lower limit of a preset difference range and less than an upper limit of the difference range.

### BRIEF DESCRIPTION OF THE DRAWINGS

FIG. 1 is a schematic diagram illustrating an electronic atomization device according to an embodiment.

FIG. 2 is a schematic diagram illustrating an electronic atomization device according to another embodiment.

FIG. 3 is a schematic diagram illustrating an electronic atomization device according to a further embodiment.

FIG. 4 is a circuit structural diagram illustrating a sampling circuit according to an embodiment.

FIG. 5 is a schematic flow diagram illustrating method for heating control according to an embodiment.

FIG. 6 is a structural block diagram illustrating a device for heating control according to an embodiment.

### DETAILED DESCRIPTION OF THE EMBODIMENTS

The Reference will be made to the accompanying drawings and embodiments to describe the present disclosure in detail, so that the objects, technical solutions and advantages of the present disclosure may be more apparent and understandable. It should be understood that the specific embodiments described herein are only used to explain the present disclosure and not intended to limit the present disclosure.

Unless otherwise defined, all terms herein, including technical and scientific terms, shall have the same meaning as commonly accepted by a person skilled in the art to which this disclosure belongs. The terms used in the specification of the invention herein are for the purpose of describing specific embodiments only and are not intended to limit the present disclosure.

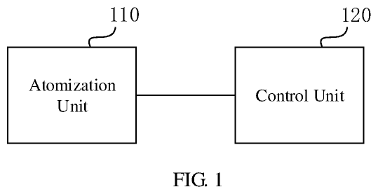

In an embodiment, as shown in FIG. 1, an electronic atomization device is provided, which includes an atomization unit 110 and a control unit 120.

The atomization unit 110 is configured to heat liquid in a cartridge to atomize the liquid.

The control unit 120 is configured to: control the atomization unit 110 to heat with a constant output of a preset power for a preset period of time in response to receiving a start-up instruction to start, and determine whether the atomization unit 110 has normal liquid content according to a variation in a resistance of the atomization unit 110 after heating; control the atomization unit 110 to heat to a preset target temperature in response to receiving a suction and heating instruction, if the atomization unit has the normal liquid content; detect whether the atomization unit 110 has the normal liquid content according to a preset time cycle; and control the atomization unit 110 to output a reduced power or stop heating, if the atomization unit has abnormal liquid content.

The constant output of the preset power means that the atomizing unit 110 performs heating while maintaining its output power constant. The preset period of time is a relative short period of time. For example, the atomizing unit 110 performs heating at an output power of 10W for 50 ms. In an embodiment, a higher or lower output power can also be used, and the output time can also be adjusted as necessary. The atomization unit 110 may perform preheating for a relative short time, so that if the liquid content is lower than a normal content, due to the relative short time for heating and thus the relative short duration for dry burning, it is not easy to damage the atomization unit 110 of the electronic atomization device, and can avoid harmful gas and burnt smell caused by long-term dry burning. If the liquid content is normal, since this heating is only to detect the liquid content of the atomization unit, heating for the relative short time can reduce the consumption of the liquid. In an embodiment, the preset period of time is less than 150 ms. In another embodiment, the preset period of time may be selected form a range of 50 ms to 100 ms. A shorter time may be selected so that a detection result can be output within the shorter time and the user can have a better experience.

The resistance of the atomization unit 110 changes with the temperature. A variation in the resistance may be calculated according to an initial resistance of the atomization unit 110 before heating and the changed resistance of the atomization unit 110 after heating for the preset period of time. According to the law of conservation of energy, it can be known that when the output power of the atomization unit 110 is constant, the output energy generated within a preset period of time is fixed. A part of the energy is absorbed by the liquid, while another part of the energy is absorbed by the atomization unit 110 itself. When the liquid is sufficient, the more energy, i.e., heat, absorbed by the liquid, the less energy absorbed by the atomization unit 110 itself, and when the liquid is insufficient, the energy absorbed by the liquid decreases, and the energy absorbed by the atomization unit 110 itself increases. Within the preset period of time, the more energy absorbed by the atomization unit 110, the greater the temperature change and the greater the variation in the resistance of the atomization unit is. Therefore, whether the current liquid content of the atomization unit is normal can be determined by comparing the variation in the resistance with a preset threshold.

The reason for the abnormal liquid content may include low liquid content or no liquid. Since the atomization unit generally includes a heating element and a liquid guiding element, the abnormal liquid content may be caused by poor flow of the liquid in the liquid guiding element in some embodiments. When the liquid in the liquid guiding element flows poorly, for example, flows during traffic jam, no liquid is heated by the heating element, so that the temperature of the heating element itself will become too high and produce burnt smell, and even the liquid guiding element will be burnt due to overheating of the heating element. The heating element may be a ceramic or metal heating element. The liquid guiding element may include a porous carrier material. The parameters related to the resistance of the atomization unit mentioned in the present disclosure, such as the initial resistance and the preheating resistance, are essentially the resistance of the heating element.

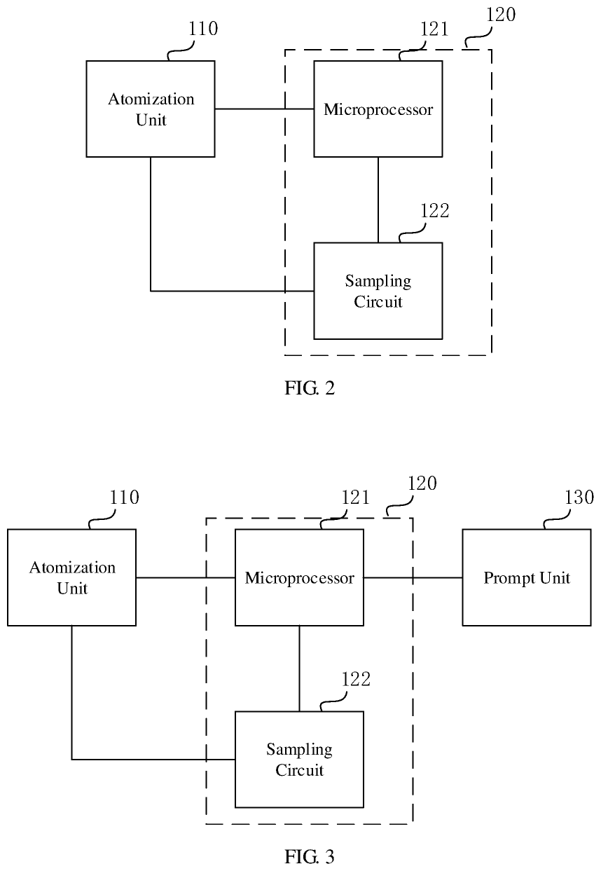

In an embodiment, as shown in FIG. 2, the control unit 120 includes a microprocessor 121 and a sampling circuit 122.

The microprocessor 121 is configured to control the sampling circuit 122 to acquire an initial resistance of the atomization unit 110 in response to receiving a start-up instruction to start.

The microprocessor 121 is further configured to: control the atomization unit 110 to heat with the constant output of the preset power for the preset period of time; control the sampling circuit 122 to acquire a preheating resistance of the atomization unit 110 after heating for the preset period of time; calculate the variation in the resistance of the atomization unit 110 according to the initial resistance and the preheating resistance; and control the atomization unit 110 to heat to the preset target temperature in response to receiving the suction and heating instruction, if the variation in the resistance is greater than a preset resistance threshold.

The initial resistance refers to a resistance when there is no heating and the temperature of the atomization unit 110 is equal to a room temperature. The pre-heating resistance is the resistance of the atomization unit 110 changing with the temperature after heating for the preset period of time.

In an embodiment, the preset power constantly output by the atomization unit 110 is greater than or equal to the lowest power that the electronic atomization device can output at the lowest voltage, and less than or equal to the highest power that the electronic atomization device can output at the highest voltage.

The determination to the variation in the resistance can be applied to full power. Even if the heating time is very short and the output power is low, the determination can be made. Even if the electric quantity of the electronic atomization device is low, the detection can be made even if a low output power can be generated.

In an embodiment, the preset power constantly output by the atomization unit 110 is less than the lowest atomization power required for the electronic atomization device to output in order to generate smoke.

The determination to the variation in the resistance can be made without heating to a temperature that can atomize the liquid, so as to avoid the problem of dry burning at a high temperature. If the liquid content of the electronic atomization device is normal, the consumption of the liquid during detection can also be reduced.

In an embodiment, the microprocessor 121 is further configured to send a PWM control signal to the atomization unit 110. The PWM control signal is configured to control the atomization unit 110 to heat at a constant temperature kept to the target temperature.

The sampling circuit 122 is further configured to acquire a real-time resistance of the atomization unit 110 and send the real-time resistance to the microprocessor 121.

The microprocessor 121 is further configured to determine a real-time temperature of the atomization unit 110 according to the real-time resistance, and adjust the PWM control signal according to the target temperature to adjust the real-time temperature of the atomization unit 110.

Pulse-width modulation (PWM) technology is an analog control method, which modulate a bias applied to a base of a transistor or a gate of a MOS transistor Q1 according to the change of the corresponding load, to achieve the change of the conduction time of the transistor or the MOS transistor Q1, so as to achieve the change of the output of the stabilized switching power supply. In this way, the output voltage of the power supply can be kept constant when the working conditions change, and it is a very effective technology for controlling the analog circuit using the digital signal of the control unit. Heating at a constant temperature refers to maintaining the temperature of the atomization unit 110 at the target temperature to heat the liquid, and heating at the constant temperature can ensure the taste of smoke and the uniform amount of smoke.

In order to keep the atomization unit 110 to heat at the constant temperature, it is necessary to acquire its real-time temperature to adjust the real-time temperature according to the difference between the real-time temperature and the target temperature. The real-time temperature of the atomization unit 110 is acquired. If the real-time temperature is not equal to the target temperature, it needs to be adjusted. If it is higher than the target temperature, it needs to be adjusted down. If it is lower than the target temperature, it needs to be adjusted up. Changing the PWM control signal is changing the control of the width of the pulse signal output, and adjusting the time of turning on and turning off of the atomization unit 110, thereby changing the voltage and achieving the purpose of changing the temperature. According to the initial resistance R₀, the initial temperature T₀, the temperature coefficient of resistance Kₜₑᵣ and the preset target temperature Tₐᵢₘ of the atomization unit 110, the target resistance Rₐᵢₘ of the atomization unit 110 heated to the target temperature is calculated as below:

Rₐᵢₘ+R₀+Kₜₑᵣ×(Tₐᵢₘ−T₀).

The microprocessor 121 may be an MCU or a PLC, both of which have the function of ADC sampling, and may cooperate with the sampling circuit 122 to acquire the heating resistance. The heating resistance refers to the resistance of the atomization unit 110 under heating control at the constant temperature. In the control process, the control according to the ratio (P), the integral (I) and the derivative (D) of the deviation is called PID control algorithm. Specifically, any one of PID control algorithms such as incremental PID algorithm, positional PID algorithm and differential forward PID can be used. In an embodiment, since the amount of smoke generated is required during the heating process of the electronic atomization device, each heating time generally does not exceed 5 seconds, and it is necessary to quickly raise the temperature to the target temperature and control it stable, the incremental PID algorithm is used. In an embodiment, before the absolute value of the difference between the heating resistance and the target resistance reaches the lower limit of the difference range, the heating is performed with the maximum output power, which can make the temperature of the atomization unit 110 reach the atomizing temperature point to atomize the liquid as soon as possible.

In order to ensure that the acquired initial resistance is the resistance of the atomization unit 110 at the room temperature, the resistance is sampled when the cartridge is loaded, and then the sampled resistance is determined. Performing sampling at a preset sampling frequency refers to sampling once every t time according to a preset time interval t. In an embodiment, the resistance is sampled for a number of times corresponding to a preset number of sampling times, to acquire a specific number of resistances of the atomization unit 110 with the specific number being equal to the sampling times. The acquired resistances are compared. If the plurality of acquired resistances of the atomization unit 110 are all equal, it means that the temperature of the atomization unit 110 has not changed, and it is determined that the atomization unit 110 is currently in an unheated state, so the resistance can be used as an initial resistance. The initial resistance record refers to the record of the initial resistance of the atomization unit 110 determined by the acquisition in an unheated state. If the plurality of acquired resistances of the atomization unit 110 change with the acquisition time (because there is no heating currently, the resistances are generally reduced), it means that the atomization unit 110 is currently not at the room temperature, but in a state after being heated, so the temperature will decrease with time, resulting in a reduction in resistance. The resistance acquired at this time cannot be used as the initial resistance. In order to quickly determine the initial resistance, the initial resistance determined in the last time may be directly acquired from the initial resistance record and used as the initial resistance of the current atomization unit 110.

In an embodiment, each PWM cycle of the PWM control signal includes a plurality of power-on phases and power-off phases.

The sampling circuit 122 is further configured to acquire a heating resistance of the atomization unit 110 in each power-off phase during one preset time cycle.

The microprocessor 121 is further configured to: acquire an output voltage of the power supply of the electronic atomization device in each power-on phase during one preset time cycle, and acquire a duty ratio of the PWM cycle corresponding to the corresponding to a respective output voltage and heating resistance during the preset time cycle; calculate a plurality of effective output powers during the preset time cycle according to each output voltage, each heating resistance and the corresponding duty ratio; and control the atomization unit 110 to stop heating, if each effective output power is less than a preset power threshold.

During the preset time cycle from t1 to t2, the output voltage V of the power supply of the electronic atomization device is acquired when each switching transistor is turned on under the control of the PWM control signal and the atomization unit 110 is powered on. Since the PWM control signal may change during one time period, it is necessary to acquire the output voltage V of the power supply of the electronic atomization device in each power-on phase. During the time period from t1 to t2 corresponding to the acquired output voltage V of the power supply, the heating resistance R of the atomization unit 110 is acquired when each switching transistor is turned off under the control of the PWM control signal and the atomization unit 110 is powered off. Since the PWM control signal may change during one time period, it is necessary to acquire the heating resistance of the atomization unit 110 in each power-off phase. Since the PWM control signal may change during one time period, the duty ratio Duty corresponding to the PWM control signal during the time period needs to be acquired. A plurality of effective output powers Pᵣₘₛ during the time period are calculated according to each output voltage V, each heating resistance R and a corresponding duty ratio Duty as below:

$${P}_{rms} = \frac{{V}^{2}}{R} \times Duty .$$

According to the law of conservation of energy, it can be known that a part of the heat generated by the atomization unit 110 is absorbed by itself to cause its own temperature to rise, and another part of the heat is absorbed by the liquid, so that the liquid is atomized. When the heating is at the constant temperature and the liquid content is normal, the liquid can absorb the heat stably, a heat balance can be reached, and the effective output power can be stabilized at a certain value. When the liquid content decreases, the energy output of the atomization unit 110 decrease accordingly. If each effective output power during the time period from t1 to t2 is less than the preset power threshold, it means that the liquid content is lower than the normal liquid content, and the atomization unit 110 needs to be controlled to stop heating to avoid dry burning. It is ensured that the user can control the atomization unit 110 to stop heating once the liquid content is insufficient during the smoking process via regular inspection, so as to avoid burnt smell or even harmful gas being sucked by the user due to dry burning.

In an embodiment, as shown in FIG. 3, the electronic atomization device further includes an prompt unit 130.

The microprocessor 121 is further configured to generate a user prompt in response to determining the liquid content of the atomization unit is lower than the normal liquid content, and send the user indication to the indication unit 130. The user prompt is adapted to prompt the user that the liquid content of the atomization unit is lower than the normal liquid content.

The prompt unit 130 is configured to provide the user prompt.

When the user liquid content is lower than an operable normal liquid content, there may be still a certain liquid content, but since the liquid content is low, it may cause dry burning; or there may be no liquid content. Therefore, when the liquid content is lower than the operable normal liquid content, it is required to prompt the user so that the user can add the liquid or replace the cartridge with enough liquid in time. In some cases, the inverted electronic atomization device may also lead to a situation where the liquid content is detected to be lower than the operable normal liquid content, and there is a safety hazard when the electronic atomization device is inverted during use. After prompting the user with the prompting information, the user may check the electronic atomization device to avoid potential safety hazards. The method of prompting may include voice prompting, text prompting, vibration prompting, or any other methods, or a combination thereof, and the type of the prompting information may be determined according to the method adopted by a specific electronic atomization device.

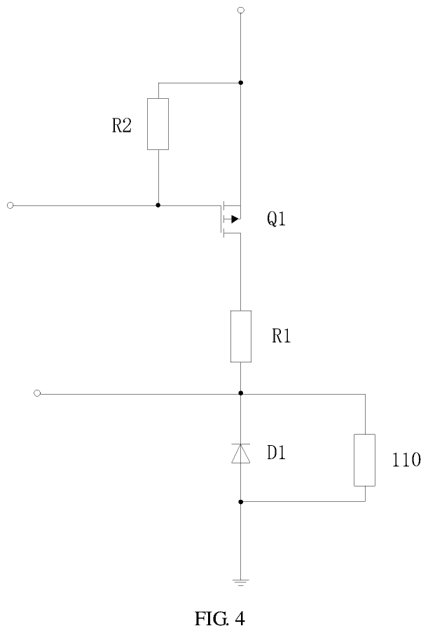

In an embodiment, as shown in FIG. 4, the sampling circuit 122 includes a MOS transistor Q1, a diode D1, a resistor R1 and a resistor R2;

The MOS transistor Q1 has a gate electrically connected to the ADC sampling terminal of the microprocessor 121, a drain electrically connected to the first end of the resistor R1, and a source electrically connected to the power supply.

The second end of the resistor R1 is electrically connected to a cathode of the diode D1, and an anode of the diode D1 is grounded.

The cathode of the diode D1 is further electrically connected to an output terminal of the microprocessor 121, the output terminal of the microprocessor 121 is further electrically connected to a first end of the atomization unit 110, and a second end of the atomization unit 110 is grounded.

The resistor R2 has a first end electrically connected to the gate of the MOS transistor Q1, and a second end electrically connected to the source of the MOS transistor Q1.

In an embodiment, the prompt unit 130 includes at least one of a display screen and a voice indicator.

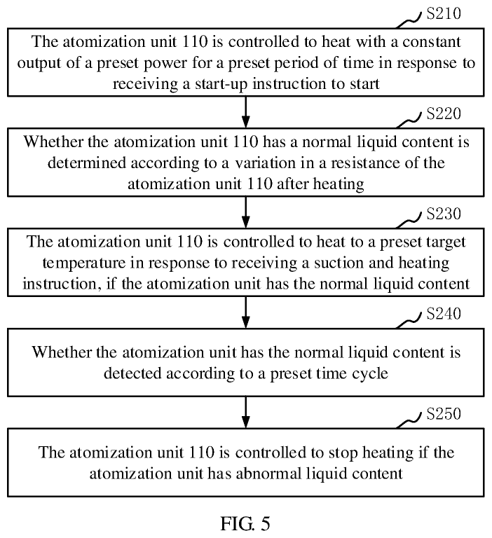

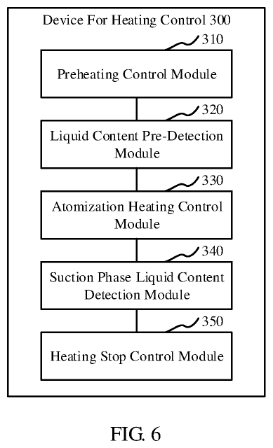

In one embodiment, as shown in FIG. 5, a method for heating control is provided, which includes the following steps.

In step 210, the atomization unit 110 is controlled to heat with a constant output of a preset power for a preset period of time in response to receiving a start-up instruction to start.

In step 220, whether the atomization unit 110 has a normal liquid content is determined according to a variation in a resistance of the atomization unit 110 after heating.

In step 220, the atomization unit 110 is controlled to heat to a preset target temperature in response to receiving a suction and heating instruction, if the atomization unit has the normal liquid content.

In step 240, whether the atomization unit has the normal liquid content is detected according to a preset time cycle.

In step 250, the atomization unit 110 is controlled to stop heating if the atomization unit has abnormal liquid content.

In an embodiment, the method for heating control further includes: sending a PWM control signal to the atomization unit 110, the PWM control signal configured to control the atomization unit 110 to heat at a constant temperature kept to a preset target temperature, each PWM cycle of the PWM control signal including a plurality of power-on phases and power-off phases; acquiring an output voltage of the power supply of the electronic atomization device in each power-on phase during a preset time cycle; acquiring a heating resistance of the atomization unit 110 in each power-off phase during a preset time cycle; acquiring a duty ratio of the PWM cycle corresponding to a respective output voltage and heating resistance during the time period; calculating a plurality of effective output powers during the time period according to each output voltage V, each heating resistance R and a corresponding duty ratio; and controlling the atomization unit 110 to stop heating, if each effective output power is less than a preset power threshold.

In an embodiment, the electronic atomization device further includes a prompt unit 130. The method further includes: generating prompt information adapted to prompt the user that the liquid content of the atomization unit is abnormal, if each effective output power is less than the power threshold; and sending the prompt information to the prompt unit 130 for presentation.

In an embodiment, the step of controlling the atomization unit 110 to heat at the constant temperature includes: acquiring a real-time temperature of the atomization unit 110; and adjusting the real-time temperature of the atomization unit 110 according to a target temperature.

In an embodiment, the step of adjusting the real-time temperature of the atomization unit 110 according to the target temperature includes: acquiring an initial resistance and an initial temperature of the atomization unit 110 in an unheated state; calculating the target resistance of the atomization unit 110 when heating to the target temperature according to the initial resistance, the initial temperature, the temperature coefficient of resistance and the preset target temperature of the atomization unit 110; acquiring a heating resistance through an ADC sampling method; and adjusting the PWM control signal by means of the PID algorithm to adjust the temperature of the atomization unit 110, when the absolute value of the difference between the heating resistance and the target resistance is greater than the lower limit of the preset difference range and less than the upper limit of the difference range.

In an embodiment, the step of adjusting the real-time temperature of the atomization unit 110 according to the target temperature further includes: controlling the atomization unit 110 to heat with the maximum output power, when the absolute value of the difference between the heating resistance and the target resistance is less than the lower limit of the difference range.

In an embodiment, the step of acquiring the initial resistance of the atomization unit 110 in an unheated state includes: sampling the resistance of the atomization unit 110 at a preset sampling frequency, in respond to identifying loading of the cartridge; comparing the acquired resistances; determining the resistances as the initial resistance of the atomization unit 110 in the unheated state, if the resistances are all equal; updating the initial resistance record; and acquiring the initial resistance determined in the last time from the initial resistance record as the initial resistance of the atomization unit 110 in the unheated state, if the acquired resistances change with the acquisition time.

Details of the heating control method may refer to the above description of the electronic atomization device, which will not be repeated here. It should be understood that although all steps in the flow diagram of FIG. 5 are sequentially displayed as indicated by the arrows, these steps are not necessarily performed in the order indicated by the arrows. Unless explicitly stated herein, the performing order of the steps is not be limited strictly, and the steps may be performed in other orders. Moreover, at least part of the steps in FIG. 5 may include a plurality of sub-steps or phases, which are not necessary to be performed simultaneously, but may be performed at different times, and for the performing order thereof, it is not necessary to be performed sequentially, but may be performed by turns or alternately with other steps or sub-steps of other steps or at least part of the phases.

In an embodiment, as shown in FIG. 6, a device for heating control 300 is provided. The device includes a number of computing modules, to be described hereinafter. Each such module is understood to be a distinct process, processor module, or code module, residing on one or more computing devices. The modules illustrated in FIG. 6 include: a preheating control module 310, an liquid content pre-detection module 320, an atomization heating control module 330, a suction phase liquid content detection module 340 and a heating stop control module 350.

The preheating control module 310 is configured to control the atomization unit 110 to heat with a constant output of a preset power for a preset period of time in response to receiving the start-up instruction to start.

The liquid content pre-detecting module 320 is configured to determine whether the atomization unit 110 has normal liquid content according to a variation in a resistance of the atomization unit 110 after heating.

The atomization heating control module 330 is configured to control the atomization unit 110 to heat to a preset target temperature in response to receiving a suction and heating instruction, when the atomization unit 110 has the normal liquid content.

The suction phase liquid content detecting module 340 is configured to detect whether the atomization unit 110 has the normal liquid content according to a preset time cycle.

The heating stop control module 340 is configured to control the atomization unit 110 to output a reduced power or stop heating, if the atomization unit 110 has abnormal liquid content.

Details of the device for heating control 300 may refer to the above description of the method for heating control, which will not be repeated here. Each of the above modules in the device for heating control 300 may be implemented in whole or in part through software, hardware or a combination thereof. When implemented through hardware, the above modules may be embedded in or independent of a processor in the computing device. When implemented through software, the above modules may stored on a computer-readable medium of the computing device or can be transmitted as one or more instruction or code on the computer-readable storage medium, so that the processor can invoke and execute the operations corresponding to the above modules. Additionally, each functional module can be integrated in one processing unit or can be separated physically, or two or more modules can be integrated into one module. The integrated modules described above can be implemented in the form of hardware or software.

In an embodiment, a computer readable storage medium is provided. A computer program executable by a processor is stored on the computer readable storage medium. When the computer program is executed by the processor, the processor is caused to: control the atomization unit 110 to heat with a constant output of a preset power for a preset period of time in response to receiving a start-up instruction to start; determine whether the atomization unit 110 has normal liquid content according to a variation in a resistance of the atomization unit 110 after heating; control the atomization unit 110 to heat to a preset target temperature in response to receiving the suction and heating instruction, if the atomization unit has the normal liquid content; detect whether the atomization unit has the normal liquid content according to a preset time cycle; and control the atomization unit 110 to output a reduced power or stop heating, if the atomization unit 110 has abnormal liquid content.

In an embodiment, when the computer program is executed by the processor, the processor is further caused to: send a PWM control signal to the atomization unit 110, the PWM control signal configured to control the atomization unit 110 to heat at a constant temperature kept to a preset target temperature, each PWM cycle of the PWM control signal including a plurality of power-on phases and power-off phases; acquire a output voltage of a power supply of the electronic atomization device in each power-on phase during one preset time cycle; acquire a heating resistance of the atomization unit 110 in each power-off phase during the preset time cycle; acquire a duty ratio of the PWM cycle corresponding to each output voltage and heating resistance during the time period; calculate a plurality of effective output powers during the time period according to each output voltage V, each heating resistance R and a corresponding duty ratio; and control the atomization unit 110 is to stop heating, if each effective output power is less than a preset power threshold.

In an embodiment, when the computer program is executed by the processor, the processor is further caused to: generate prompt information adapted to prompt the user that the liquid content of the atomization unit is abnormal, if each effective output power is less than the power threshold; and send the prompt information to the prompt unit 130 for presentation.

In an embodiment, when the computer program is executed by the processor, the processor is further caused to: acquire a real-time temperature of the atomization unit 110; and adjust the real-time temperature of the atomization unit 110 according to a target temperature.

In an embodiment, when the computer program is executed by the processor, the processor is further caused to: acquire an initial resistance and an initial temperature of the atomization unit 110 in an unheated state; calculate the target resistance of the atomization unit 110 when heating to the target temperature according to the initial resistance, the initial temperature, the temperature coefficient of resistance and the preset target temperature of the atomization unit 110; acquire a heating resistance through an ADC sampling method; adjust the PWM control signal by means of the PID algorithm to adjust the temperature of the atomization unit 110, when the absolute value of the difference between the heating resistance and the target resistance is greater than the lower limit of the preset difference range and less than the upper limit of the difference range.

In an embodiment, when the computer program is executed by the processor, the processor is further caused to: control the atomization unit 110 to heat with the maximum output power, when the absolute value of the difference between the heating resistance and the target resistance is less than the lower limit of the difference range.

In an embodiment, when the computer program is executed by the processor, the processor is further caused to: sample the resistance of the atomization unit 110 at a preset sampling frequency, in respond to identifying loading of the cartridge; comparing the acquired resistances; determine the resistances as the initial resistance of the atomization unit 110 in the unheated state, if the resistances are all equal; update the initial resistance record; and acquire the initial resistance determined in the last time from the initial resistance record as the initial resistance of the atomization unit 110 in the unheated state, if the acquired resistances change with the acquisition time.

A person skilled in the art should understand that the processes of the methods in the above embodiments can be, in full or in part, implemented by computer-readable instructions instructing underlying hardware. The computer-readable instructions can be stored in a computer-readable storage medium and executed by at least one processor in the computer operating system. The computer-readable instructions can include the processes in the embodiments of the various methods when it is being executed. Any references to memory, storage, databases, or other media used in various embodiments provided herein may include non-transitory and/or transitory memory. Non-transitory memory can include read only memory (ROM), programmable ROM (PROM), electrically programmable ROM (EPROM), electrically erasable programmable ROM (EEPROM), or flash memory. Transitory memory may include random access memory (RAM) or external high-speed cache memory. By way of illustration and not limitation, RAM is available in many forms such as static RAM (SRAM), dynamic RAM (DRAM), synchronous DRAM (SDRAM), double data rate SDRAM (DDR SDRAM), enhanced SDRAM (ESDRAM), synchronization chain Synchlink DRAM (SLDRAM), memory Bus (Rambus) direct RAM (RDRAM), direct memory bus dynamic RAM (DRDRAM), and memory bus dynamic RAM (RDRAM).

Those skilled in the art can apparently appreciate upon reading the disclosure of this application that the respective technical features involved in the respective embodiments can be combined arbitrarily between the respective embodiments as long as they have no collision with each other. Of course, the respective technical features mentioned in the same embodiment can also be combined arbitrarily as long as they have no collision with each other.

The aforementioned embodiments merely represent several embodiments of the present disclosure, and the description thereof is more specific and detailed, but it should not be construed as limiting the scope of the present disclosure. It should be noted that, several modifications and improvements may be made for those of ordinary skill in the art, without departing from the concept of the present disclosure, and these are all during the protection scope of the present disclosure. Therefore, the protection scope of the present disclosure shall be subject to the appended claims.

What is claimed is:

1. An electronic atomization device, comprising:
an atomization unit, configured to heat liquid in the electronic atomization device to atomize the liquid; and
a control unit, configured to:
send a Pulse-width modulation (PWM) control signal to the atomization unit, and the PWM control signal is configured to control the atomization unit to heat at a constant temperature kept to a target temperature;
calculate an effective output power of the atomization unit;
determine whether oil content of the atomization unit is abnormal according to the effective output power; and
control the atomization unit to output a reduced power or stop heating, when it is determined that the oil content of the atomization unit is abnormal.

2. The electronic atomization device according to claim 1, wherein the control unit comprises:
a microprocessor, configured to send a PWM control signal to the atomization unit, and the PWM control signal is configured to control the atomization unit to heat at a constant temperature kept to the target temperature; and
a sampling circuit, configured to acquire a real-time resistance of the atomization unit and send the real-time resistance to the microprocessor; and
wherein the microprocessor is further configured to determine a real-time temperature of the atomization unit according to the real-time resistance, and adjust the PWM control signal according to a difference between the real-time temperature and the target temperature to adjust the real-time temperature of the atomization unit to obtain the target temperature.

3. The electronic atomization device according to claim 2, wherein each PWM cycle of the PWM control signal comprises a plurality of power-on phases and power-off phases;
the sampling circuit is further configured to acquire a heating resistance of the atomization unit in each power-off phase during one preset time cycle, and send the heating resistance to the microprocessor; and
the microprocessor is further configured to:
acquire an output voltage of a power supply of the electronic atomization device in each power-on phase during the preset time cycle, and acquire a duty ratio of the PWM cycle corresponding to a respective output voltage and heating resistance during the preset time cycle;
calculate a plurality of effective output powers during the preset time cycle according to each output voltage, each heating resistance and the corresponding duty ratio; and
control the atomization unit to output the reduced power or stop heating, if each effective output power is less than a preset power threshold.

4. The electronic atomization device according to claim 3, further comprising a prompt unit configured to provide a user prompt adapted to prompt a user the atomization unit has the abnormal liquid content, wherein the microprocessor is further configured to generate the user prompt in response to determining the atomization unit has the abnormal liquid content.

5. The electronic atomization device according to claim 4, wherein the prompt unit comprises at least one of a display screen and a voice prompter.

6. The electronic atomization device according to claim 2, wherein:
the sampling circuit comprises: a MOS transistor Q1, a diode D1, a resistor R1 and a resistor R2;
the MOS transistor Q1 has a gate electrically connected to an ADC sampling terminal of the microprocessor, a drain electrically connected to a first end of the resistor R1, and a source electrically connected to a power supply;
a second end of the resistor R1 is electrically connected to a cathode of the diode D1, and an anode of the diode D1 is grounded;
the cathode of the diode D1 is further electrically connected to an output terminal of the microprocessor, the output terminal of the microprocessor is further electrically connected to a first end of the atomization unit, and a second end of the atomization unit is grounded; and
the resistor R2 has a first end electrically connected to the gate of the MOS transistor Q1, and a second end electrically connected to the source of the MOS transistor Q1.

7. A method for heating control applied to an electronic atomization device, the electronic atomization device including an atomization unit configured to heat liquid in the electronic atomization device to atomize the liquid, and a control unit, the control unit executing the heating control method, the method comprising:
sending a Pulse-width modulation (PWM) control signal to the atomization unit, wherein the PWM control signal is configured to control the atomization unit to heat at a constant temperature kept to a target temperature;
calculating an effective output power of the atomization unit;
determining whether oil content of the atomization unit is abnormal according to the effective output power; and
controlling the atomization unit to output a reduced power or stop heating when it is determined that the oil content of the atomization unit is abnormal.

8. The method for heating control according to claim 7, wherein each PWM cycle of the PWM control signal comprises a plurality of power-on phases and power-off phases, and the calculating the effective output power of the atomization unit comprises:
acquiring an output voltage of a power supply of the electronic atomization device in each power-on phase during one preset time cycle;
acquiring a heating resistance of the atomization unit in each power-off phase during the preset time cycle;
acquiring a duty ratio of the PWM cycle corresponding to each output voltage and heating resistance during the time period; and
calculating a plurality of effective output powers during the time period according to each output voltage, each heating resistance and a corresponding duty ratio.

9. The method for heating control according to claim 7, wherein the determining whether the oil content of the atomization unit is abnormal according to the effective output power comprises:
determining the oil content of the atomization unit is abnormal if each effective output power is less than a preset power threshold.

10. The method for heating control according to claim 9, wherein the electronic atomization device further comprises a prompt unit, and the method further comprises:
generating prompt information adapted to prompt the user that the liquid content of the atomization unit is abnormal, if each effective output power is less than the power threshold; and
sending the prompt information to the prompt unit for presentation.

11. The method for heating control according to claim 7, wherein the controlling the atomization unit to heat at a constant temperature kept to the target temperature comprises:
acquiring a real-time temperature of the atomization unit; and
adjusting the real-time temperature of the atomization unit according to the target temperature.

12. The method for heating control according to claim 11, wherein the adjusting the real-time temperature of the atomization unit according to the target temperature comprises:
acquiring an initial resistance and an initial temperature of the atomization unit in an unheated state;
calculating a target resistance of the atomization unit when heating to the target temperature according to the initial resistance, the initial temperature, the temperature coefficient of resistance and the preset target temperature of the atomization unit;
acquiring a heating resistance through an ADC sampling method; and
adjusting the PWM control signal by means of a PID algorithm to adjust the real-time temperature of the atomization unit, when an absolute value of a difference between the heating resistance and the target resistance is greater than a lower limit of a preset difference range and less than an upper limit of the difference range.

13. The method for heating control according to claim 12, wherein the adjusting the real-time temperature of the atomization unit according to the target temperature comprises:
controlling the atomization unit to heat with the maximum output power, when the absolute value of the difference between the heating resistance and the target resistance is less than the lower limit of the difference range.

14. The method for heating control according to claim 12, wherein the acquiring an initial resistance of the atomization unit in an unheated state comprises:
sampling the resistance of the atomization unit at a preset sampling frequency, in respond to identifying loading of the cartridge;
comparing the acquired resistances;
determining the resistances as the initial resistance of the atomization unit in the unheated state, if the resistances are all equal; updating the initial resistance record; and
acquiring the initial resistance determined in the last time from the initial resistance record as the initial resistance of the atomization unit in the unheated state, if the acquired resistances change with the acquisition time.

15. A computer device applied to an electronic atomization device, the electronic atomization device including an atomization unit configured to heat the liquid in the electronic atomization device to atomize the liquid, wherein the computer device includes a processor, and a memory on which instructions are stored, and when the instructions are executed by the processor, the processor is caused to perform a method comprising:
sending a PWM control signal to the atomization unit, wherein the PWM control signal is configured to control the atomization unit to heat at a constant temperature kept to the target temperature;
calculating an effective output power of the atomization unit;
determining whether oil content of the atomization unit is abnormal according to the effective output power; and
controlling the atomization unit to output the reduced power or stop heating when it is determined that the oil content of the atomization unit is abnormal.

16. The computer device according to claim 15, wherein each PWM cycle of the PWM control signal comprises a plurality of power-on phases and power-off phases, and wherein the step of calculating the effective output power of the atomization unit comprises:
acquiring an output voltage of a power supply of the electronic atomization device in each power-on phase during one preset time cycle;
acquiring a heating resistance of the atomization unit in each power-off phase during the preset time cycle;
acquiring a duty ratio of the PWM cycle corresponding to each output voltage and heating resistance during the time period; and
calculating a plurality of effective output powers during the time period according to each output voltage, each heating resistance and a corresponding duty ratio.

17. The computer device according to claim 15, wherein the step of determining whether the oil content of the atomization unit is abnormal according to the effective output power comprises:
determining the oil content of the atomization unit is abnormal if each effective output power is less than a preset power threshold.

18. The computer device according to claim 17, wherein when the instructions are executed by the processor, the processor is caused to further perform the following steps of the method:
generating prompt information adapted to prompt the user that the liquid content of the atomization unit is abnormal, if each effective output power is less than the power threshold; and
sending the prompt information to the prompt unit for presentation.

19. The computer device according to claim 15, wherein the step of controlling the atomization unit to heat at a constant temperature kept to the target temperature comprises:
acquiring a real-time temperature of the atomization unit; and
adjusting the real-time temperature of the atomization unit according to the target temperature.

20. The computer device according to claim 19, wherein the step of adjusting the real-time temperature of the atomization unit according to the target temperature comprises:
acquiring an initial resistance and an initial temperature of the atomization unit in an unheated state;
calculating a target resistance of the atomization unit when heating to the target temperature according to the initial resistance, the initial temperature, the temperature coefficient of resistance and the preset target temperature of the atomization unit;
acquiring a heating resistance through an ADC sampling method; and
adjusting the PWM control signal by means of a PID algorithm to adjust the real-time temperature of the atomization unit, when an absolute value of a difference between the heating resistance and the target resistance is greater than a lower limit of a preset difference range and less than an upper limit of the difference range.
